(19) United States
(12) Patent Application Publication
(10) Pub. No.: US 2026/0132878 A1
(43) Pub. Date: May 14, 2026

(54) FLUID DELIVERY SYSTEM

(71) Applicant: Compart Systems Pte. Ltd., Singapore (SG)

(72) Inventors: John C. Lantz, Dallas, TX (US); Kim N. Vu, Yorba Linda, CA (US); Michael Fisher, Phoenix, AZ (US); Frederick Rezaei, Phoenix, AZ (US)

(21) Appl. No.: 19/352,008

(22) Filed: Oct. 7, 2025

Related U.S. Application Data
(60) Provisional application No. 63/704,386, filed on Oct. 7, 2024.

(51) Int. Cl. F16L 41/08; H10P 72/00

(52) U.S. Cl. CPC F16L 41/086; H10P 72/0402

(57) ABSTRACT

A delivery system can include a bridge portion, wherein the bridge portion includes a flared connection protrusion.

### FIELD OF THE DISCLOSURE

The present disclosure is directed to fluid delivery systems, and more particularly to extreme flow rate and/or high temperature surface mount fluid delivery systems for use in the semiconductor processing and petrochemical industries.

### BACKGROUND OF THE ART

Fluid delivery systems are used in many modern industrial processes for conditioning and manipulating fluid flows to provide controlled admittance of desired substances into the processes. Practitioners have developed an entire class of fluid delivery systems which have fluid handling components removably attached to flow substrates containing fluid pathway conduits. The arrangement of such flow substrates establishes the flow sequence by which the fluid handling components provide the desired fluid conditioning and control. The interface between such flow substrates and removable fluid handling components is standardized and of few variations. Such fluid delivery system designs are often described as modular or surface mount systems. Representative applications of surface mount fluid delivery systems include gas panels used in semiconductor manufacturing equipment and sampling systems used in petrochemical refining. The many types of manufacturing equipment used to perform process steps making semiconductors are collectively referred to as tools. Embodiments of the present invention relate generally to fluid delivery systems for semiconductor processing and specifically to surface mount fluid delivery systems that are specifically well suited for use in extreme flow rate and/or high temperature applications where the process fluid is to be heated to a temperature above ambient. Aspects of the present invention are applicable to surface mount fluid delivery system designs whether of a localized nature or distributed around a semiconductor processing tool.

Industrial process fluid delivery systems have fluid pathway conduits fabricated from a material chosen according to its mechanical properties and considerations of potential chemical interaction with the fluid being delivered. Stainless steels are commonly chosen for corrosion resistance and robustness, but aluminum or brass may be suitable in some situations where cost and ease of fabrication are of greater concern. Fluid pathways may also be constructed from polymer materials in applications where possible ionic contamination of the fluid would preclude using metals. The method of sealingly joining the fluid handling components to the flow substrate fluid pathway conduits is usually standardized within a particular surface mount system design in order to minimize the number of distinct part types. Most joining methods use a deformable gasket interposed between the fluid component and the flow substrate to which it is attached.

A collection of fluid handling components assembled into a sequence intended for handling a single fluid species is frequently referred to as a gas stick. The equipment subsystem comprised of several gas sticks intended to deliver process fluid to a particular semiconductor processing chamber is often called a gas panel. During the 1990s several inventors attacked problems of gas panel maintainability and size by creating gas sticks wherein the general fluid flow path is comprised of passive metallic structures, containing the conduits through which process fluid moves, with valves and like active (and passive) fluid handling components removably attached thereto. The passive fluid flow path elements have been variously called manifolds, substrates, blocks, and the like, with some inconsistency even within the work of individual inventors. This disclosure chooses to use the terminology flow substrate or manifold to indicate fluid delivery system elements which contain passive fluid flow path(s) that may have other fluid handling devices mounted there upon.

### SUMMARY OF THE INVENTION

In some embodiments, a delivery system can include a bridge portion, wherein the bridge portion includes a flared connection protrusion.

In some embodiments, a delivery system can include a flow substrate, wherein the flow substrate includes a flared connection depression.

In some embodiments, a delivery system can include a bridge portion, wherein the bridge portion includes a flared connection protrusion. In some embodiments, the delivery system can include a flow substrate, wherein the flow substrate includes a flared connection depression, wherein the flared connection protrusion is configured to be inserted into the flared connection depression.

### BRIEF DESCRIPTION OF THE DRAWINGS

FIG. 1 depicts an embodiment of a manifold as seen in the prior art.

FIG. 2A depicts a top isometric view of a bridge portion of a modular flow substrate, in accordance with embodiments of the present disclosure.

FIG. 2B depicts a bottom isometric view of the bridge portion, depicted in FIG. 2A, in accordance with embodiments of the present disclosure.

FIG. 3 depicts a flow substrate with a pair of flared connection depressions, in accordance with embodiments of the present disclosure.

FIG. 4 depicts an isometric top view of a bridge portion and a flow substrate, together which form a modular flow substrate when connected, in accordance with embodiments of the present disclosure.

FIG. 5A depicts a top isometric view of a bridge portion that includes manifold mounting apertures, in accordance with embodiments of the present disclosure.

FIG. 5B depicts a bottom isometric view of the bridge portion depicted in FIG. 5A, further depicting a conduit port defined in a bottom connecting surface of the bridge portion, in accordance with embodiments of the present disclosure.

FIG. 6 depicts a modular flow substrate that includes a pair of flow substrates coupled with one another via a bridge portion and a multiport manifold, in accordance with embodiments of the present disclosure.

FIG. 7 depicts a flow substrate with a pair of flared connection depressions, in accordance with embodiments of the present disclosure.

FIG. 8 depicts a pair of flow substrates fluidly coupled with one another, in accordance with embodiments of the present disclosure.

FIGS. 9A and 9B further depict details associated with bridge portions depicted in FIG. 8, in accordance with embodiments of the present disclosure.

FIGS. 10A and 10B further depict isometric top and bottom views of a bridge portion, in accordance with embodiments of the present disclosure.

FIG. 11A depicts a top isometric view of a bridge coupled with a flow substrate, along with a K1S manifold, in accordance with embodiments of the present disclosure.

FIG. 11B depicts a top isometric view of a bridge coupled with a flow substrate, along with an ICS manifold, in accordance with embodiments of the present disclosure.

### DETAILED DESCRIPTION

Various embodiments are described herein of various apparatus and/or systems. Numerous specific details are set forth to provide a thorough understanding of the overall structure, function, manufacture, and/or use of the embodiments as described in the specification and illustrated in the accompanying drawings. It will be understood by those skilled in the art, however, that the embodiments may be practiced without such specific details. In other instances, well-known operations, components, and elements have not been described in detail so as not to obscure the embodiments described in the specification. Those of ordinary skill in the art will understand that the embodiments described and illustrated herein are non-limiting examples, and thus it can be appreciated that the specific structural and functional details disclosed herein may be representative and do not necessarily limit the scope of the embodiments, the scope of which is defined solely by the appended claims.

Reference throughout the specification to “various embodiments,” “some embodiments,” “one embodiment,” “an embodiment,” “an exemplary embodiment,” or the like, means that a particular feature, structure, or characteristic described in connection with the embodiment is included in at least one embodiment. Thus, appearances of the phrases “in various embodiments,” “in some embodiments,” “in one embodiment,” “in an embodiment,” “in an exemplary embodiment,” or the like, in places throughout the specification are not necessarily all referring to the same embodiment. Furthermore, the particular features, structures, or characteristics may be combined in any suitable manner in one or more embodiments. Thus, the particular features, structures, or characteristics illustrated or described in connection with one embodiment may be combined, in whole or in part, with the features structures, or characteristics of one or more other embodiments without limitation given that such combination is not illogical or non-functional.

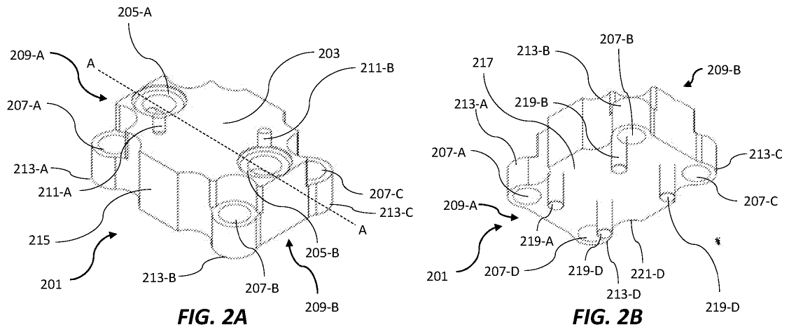

Referring now to the drawings wherein like reference numerals are used to identify identical or similar components in the various views, an overview of the basic concept and design of the apparatus is shown schematically in FIG. 2A.

Embodiments of the present invention are directed to a surface mount fluid delivery flow substrate that is specifically adapted for use in extreme flow rate and/or high temperature applications where the process fluid is to be heated (or cooled) to a temperature above (or below) that of the ambient environment. As used herein, and in the context of semiconductor process fluid delivery systems, the expression “extreme flow rate” corresponds to gas flow rates above approximately 50 SLM or below approximately 50 SCCM. A significant aspect of the present invention is the ability to fabricate flow substrates having fluid pathway conduits with a cross-sectional area (size) substantially larger or smaller than other surface mount architectures.

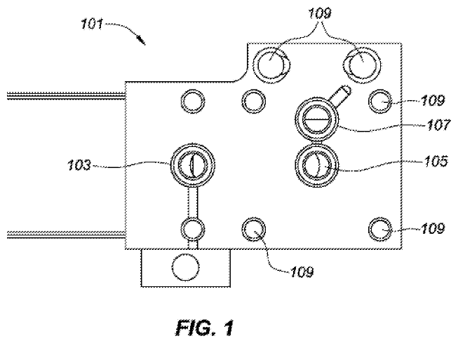

FIG. 1 illustrate an embodiment of a flow substrate 101 as seen in the prior art. The flow substrate 101 can be formed from a solid block of material with machined parts creating a first conduit port 103, a second conduit port 105, a third conduit port 107, and a plurality of mounting apertures 109. The flow substrate 101 can comprise a variety of configurations as may be required or various delivery flow systems. Fluid pathways can be made between conduit ports to move a fluid through the flow substrate. In some embodiments the flow substrate 101 can comprise multiple distinct fluid pathways. As seen in FIG. 1 the flow substrate 101 is created from a single block of material that is machined to create fluid pathways, mounting apertures, and other portions within the flow substrate. Additionally, excess material is removed from the flow substrate 101 to create the finished product. However, the materials used in the flow substrate 101 can be costly and excess material and machining costs are needed to make flow substrates in this manner. Additionally, the fluid pathways and other components of a flow substrate as seen in FIG. 1 are not able to be easily modified or changed after creation. In contrast, the separate component pieces of flow substates as described herein limit the amount of material removed from the finished product and can allow for more modular design and creation of finished flow substrates.

While the flow substrate seen in FIG. 1 can allow for the direction of a fluid to be changed, the flow substrate of FIG. 1 requires the specialized manufacture of these substrates for inclusion within an integrated subassembly. The flow substrate seen above can require larger blocks for initial machining and create additional waste material and manufacturing processes. In some of the embodiments described herein, 10% to 20% material savings can be achieved using the modular flow substrate, in accordance with embodiments of the present disclosure, in place of the prior art methods and materials. In contrast, the modular flow substrate described below can minimize the number of fluid conduit ports and seals needed to build standardized fluid delivery sticks. Flow substrates for each fluid delivery stick can be fastened to a standardized bracket and each fluid delivery stick arrangement can be assembled and tested as an integrated subassembly. Use of the modular flow substrate described herein can allow for the direction of fluid to be changed without requiring more material width to create diverted ports. Additionally, the modular flow substrate can allow for the redirection of fluid or gas from the linear flow path without increasing the width of a standard fluid delivery system material while providing multiple flow direction paths diverted from the linear flow path. In some of the embodiments described herein, the linear flow path can comprise a plurality of i-Block components while the i-Bridge can be used to divert a fluid or gas away from the linear flow path. As a result, standardized components can be used for the linear flow path, while the diverting components can be added when the path needs to be diverted, but omitted from the linear flow path components when not needed. As a result, standardized materials can be used which can reduce manufacturing costs, wasted materials, the number of different components within the integrated subassembly and ease assembly of the components. As seen and described throughout the application, the redirected fluid path from the linear flow path can comprise any three-dimensional direction without the need of a specialized linear flow path component for that section of the subassembly. Additionally, the prior art flow substrate illustrated in FIG. 1 needs to be welded to a manifold to such as an ICS manifold, K1S manifold, or other type. In contrast, as seen herein, the i-Bridge component of the modular flow substrate comprises at least one mounting aperture that can be used to fasten the i-Bridge to a manifold during assembly. This can decrease complexity of design within the system and ease, removal, replacement, or reconfiguration before, during, or after installation. Further, as the components described herein are coupled through fasteners, dowels, screws or other types of joining devices, the assembly can more easily be done at a customer facility.

Additionally, embodiments of the present disclosure can provide corresponding portions of a respective bridge and flow substrate, which can be aligned and indexed with one another. In some embodiments, such alignment and indexing can be accomplished without the use of alignment pins and alignment lumens, which can normally be used for alignment and indexing of various components of a modular flow substrate, for example a bridge and flow substrate. Further aspects of the present disclosure can include a multiport manifold conduit. Whereas prior manifolds associated with flow substrates include one port, embodiments of the present disclosure can include manifolds with a plurality of conduits. Such embodiments can be useful for directing fluid and/or gas flow to a plurality of fluid handling components.

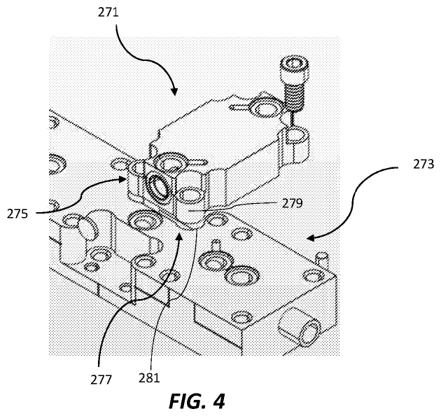

FIG. 2A depicts a top isometric view of a bridge portion 201 of a modular flow substrate, in accordance with embodiments of the present disclosure. Further embodiments associated with a modular flow substrate are depicted and discussed in relation to FIG. 4. Furthermore, additional aspects of the present disclosure will be apparent upon review of PCT pat. app. no. PCT/IB2024/056238, which is hereby incorporated by reference as though fully set forth herein. In some embodiments, the bridge can comprise a solid block of material (such as stainless steel) and can comprise a component attachment surface to which another component, such as a fluid handling component (i.e. a valve, pressure transducer, filter, regulator, etc.) can be attached. In some embodiments, the bridge 201 can include a component attachment surface 203, a first and second conduit port 205-A, 205-B, a fluid pathway extending from the first and second bridge conduit ports 205-A, 205-B, at least one mounting aperture 207-A, 207-B, 207-C, 207-D, a flared connection protrusion 209-A, 209-B, and a leak port 211-A, 211-B. In the illustrated embodiment, the flared connection protrusion 209-A, 209-B of the bridge can comprise a flared connection protrusion that extends from the bridge and fits within an associated connection depression, as further depicted and discussed in relation to FIG. 4, such that the two components of the modular flow substrate can be joined.

With particular reference to the flared connection protrusion 209-B, the connection protrusion can protrude away from a body portion 215 of the bridge 201 and parallel with a planar surface defined by the component attachment surface 203, and along axis AA. As depicted, the flared connection protrusion 209-B can include a first and second lobe portion 213-B, 213-C, which can extend outward from each corner of the flared connection protrusion 209-B. In some embodiments, as depicted, each one of the first and second lobe portions 213-B, 213-C can extend along a longitudinal axis AA along which the bridge portion 201 extends. As further depicted, in some embodiments, each lobe portion 213-A, 213-B can extend in a direction transverse to the longitudinal axis AA. Such a configuration can allow for indexing of the flared connection protrusion 209-B with a correspondingly shaped connection depression, as further discussed in relation to FIG. 4. For instance, the flared connection protrusion 209-B cannot be laterally slid into position into the corresponding connection depression, which can be prevented by the laterally extending lobe portions 213-A, 213-B. In contrast, the flared connection protrusion 209-B can be vertically slid into the corresponding connection depression, thereby eliminating lateral shifting of the connection protrusion 209-B in a direction along the longitudinal axis AA and ensuring correct alignment with an article (e.g., substrate) that defines the connection depression.

In some embodiments, the bridge 201 can include a pair of flared connection protrusions 209-A, 209-B, as depicted in FIG. 2A. However, in some embodiments, the bridge 201 can include one connection protrusion. As depicted in FIG. 2A, each one of the flared connection protrusions 209-A, 209-B can include a first and second lobe portion 213-A, 213-B, 213-C, 213-D (further depicted in FIG. 2B) and each flared connection protrusion 209-A, 209-B can be located on opposite sides of the bridge 201, along axis AA.

In embodiments where the bridge portion 201 includes first and second flared connection protrusions 209-A, 209-B, the flared connection protrusions can be disposed on opposite sides of the body portion 215, as depicted in FIG. 2A. For example, each of the connection protrusions 209-A, 209-B can extend away from one another along axis AA, thereby protruding away from the body portion 215. In some embodiments, as depicted and discussed herein, the connection protrusions 209-A, 209-B can extend past an end of a body portion of the bridge. For example, the first and second lobe portions 213-A, 213-B can extend along the longitudinal axis AA. Inclusion of first and second flared connection protrusions 209-A, 209-B can allow for connection of first and second fluid delivery substrates, thereby forming a modular flow substrate, as further discussed herein.

FIG. 2B depicts a bottom isometric view of the bridge portion 201, depicted in FIG. 2A, in accordance with embodiments of the present disclosure. FIG. 2B further illustrates a fluid delivery substrate attachment surface 217. In some embodiments, upon connection of the bridge portion 201 with the fluid delivery substrate, the fluid delivery substrate attachment surface 217 can be disposed against a corresponding portion of the fluid delivery substrate. As further depicted in FIG. 2B, a plurality of alignment pins 219-A, 219-B, 219-C, 219-D can protrude from the fluid delivery substrate attachment surface 217. Although four alignment pins are depicted, fewer or greater than four alignment pins can be included on the bridge portion 201. In some embodiments, as discussed herein, the lobe portions 213-A, 213-B, 213-C, 213-D can allow for indexing of the flared connection protrusions 209-A, 209-B with correspondingly shaped connection depressions, thereby alleviating the need for alignment pins. Thus, in some embodiments that include flared connection protrusions, no alignment pins may be included on the fluid delivery substrate attachment surface 217 of the bridge portion 201.

As depicted in FIG. 2B, exteriors of the lobe portions 213-A, 213-B, 213-C, 213-D can be semicylindrical in shape. However, in some embodiments, the exteriors of the lobe portions 213-A, 213-B, 213-C, 213-D can be of other shapes, for example, the lobe portions 213-A, 213-B, 213-C, 213-D can include a combination of straight planar surfaces. In some embodiments, the exteriors of the lobe portions 213-A, 213-B, 213-C, 213-D can include a combination of curved surfaces. In some embodiments, the exteriors of the lobe portions 213-A, 213-B, 213-C, 213-D can include a combination of curved and planar surfaces. In some embodiments, the exteriors of the lobe portions 213-A, 213-B, 213-C, 213-D can include a combination of curved and planar surfaces. In some embodiments, the lobe portions 213-A, 213-B, 213-C, 213-D can be of another shape (e.g., square, triangular, hexagonal, oblong, rectangular, etc.).

In some embodiments, the perimeter of the bridge 201 can include one or more recessed connection portions 221-D. Although the bridge 201 is depicted as including four recessed connection portions, for ease, only one recessed connection portion 221-D is discussed, however the other recessed connection portions can include the same or similar features. In some embodiments, the recessed connection portion 221-D can be a semicircular recessed portion, which can provide room for additional fasteners to pass on either side of the flared connection protrusions 209-A, 209-B. In some embodiments, the recessed connection portion 221-D can be of another shape (e.g., square recess, triangular recess, hexagonal recess, oblong recess, rectangular recess, etc.), which can provide room for additional fasteners to pass.

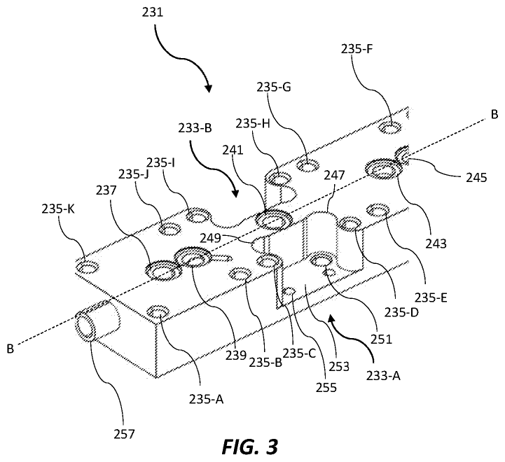

FIG. 3 depicts a flow substrate 231 with a pair of flared connection depressions 233-A, 233-B, in accordance with embodiments of the present disclosure. In some embodiments, the flow substrate 231 can include a plurality of mounting apertures 235-A, 235-B, . . . , 235-K. In some embodiments, one or more of a valve, pressure transducer, filter, and regulator can be attached to the flow substrate 231 via one or more of the connection apertures 235-A, 235-B, . . . , 235-K. In some embodiments, the flow substrate can further include a first conduit port 237, second conduit port 239, third conduit port 241, fourth conduit port 243, and fifth conduit port 245, to which one or more valves, pressure transducers, filters, regulators, etc. can be fluidly coupled.

As further depicted in FIG. 3, the flow substrate 231 can include flared connection depressions 233-A, 233-B. For ease, features of the flared connection depression 233-A are discussed, although the flared connection depression 233-B can include the same or similar features. As depicted, the flared connection depression 233-B can include flared recesses 247, 249, which can correspond to lobe portions 213 of the flared connection protrusions 209-A, 209-B, as discussed herein, particularly in reference to FIGS. 2A and 2B. As depicted, the flared connection depression 233-A can include a pair of flared recesses 247, 249, each of which are depicted as having a semi cylindrical profile, which can match the profile of each lob portion 213. Although a pair of flared recesses 247, 249 are depicted, embodiments of the present disclosure can include one or more flared recesses. As depicted, each of the flared recesses can extend laterally outward along the longitudinal axis BB and inward in a transverse direction to the longitudinal axis BB. Such a configuration can provide for a unique profile, which can allow for indexing between the flared connection protrusions 209-A, 209-B and the fluid delivery substrate 231.

In some embodiments, the flared recesses 247, 249 can also provide for spacing to allow for a mounting aperture 251 to be defined at a base of the flared connection depression 233-A, in a connection surface 253. For example, a fastener can be disposed through mounting aperture 207-B (FIGS. 2A, 2B) and mounting aperture 251. Although indexing lumens 255 are depicted as being defined in the connection surface, as discussed herein, in some embodiments, no indexing lumens may be present, as a result of the interaction between the flared connection protrusion and the flared connection depression. In some embodiments, the indexing lumens can correspond with respective ones of the alignment pins 219, as further discussed herein, for example in relation to FIG. 2B. In some embodiments, the respective ones of the alignment pins 219 can be inserted into corresponding ones of the indexing lumens. As such, the only relative movement between a flow substrate and a corresponding bridge can be in a single (e.g., vertical direction).

As further depicted, in some embodiments, the flow substrate 231 can include a manifold conduit port 257. In some embodiments, the manifold conduit port 257 can be fluidly connected to and adjacent one or more of the conduit ports. Although one manifold conduit port 257 is depicted, the flow substrate 231 can include a plurality of manifold conduit ports.

FIG. 4 depicts an isometric top view of a bridge portion 271 and a flow substrate 273, together which form a modular flow substrate when connected, in accordance with embodiments of the present disclosure. In some embodiments, the bridge portion 271 and the flow substrate 273 can include the same or similar features as those discussed in relation to FIGS. 2A, 2B, and 3. As further depicted in FIG. 4, the bridge portion can include a flared connection protrusion 275 and the flow substrate 273 can include a flared connection depression 277 into which the flared connection protrusion 275 can be inserted. The corresponding shapes of the lobe portions 279 of the flared connection protrusions 275 and the flared recesses 281 of the flared connection depression 277 can limit movement between the bridge portion 271 and the flow substrate 273 to movement in the vertical direction. Thus, upon insertion of the flared connection protrusion 275 into the flared connection depression 277, correct placement of the bridge portion 271 can be attained with respect to the flow substrate 273. Once the flared connection protrusion 275 has been inserted into the flared connection depression movement can be limited to that in the vertical direction, as discussed herein. Accordingly, in some embodiments, one or more fasteners can be placed in mounting apertures defined by the flared connection protrusions 275, securing the bridge portion 271 to the flow substrate.

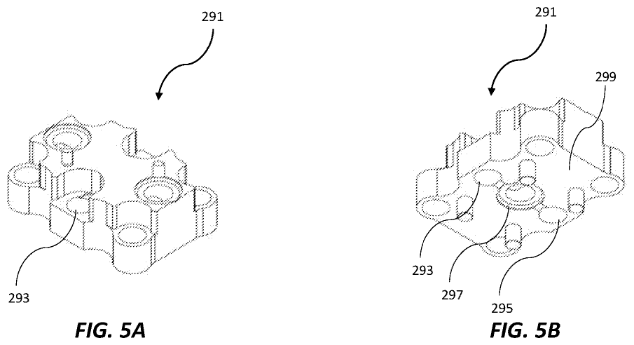

FIG. 5A depicts a top isometric view of a bridge portion 291 that includes manifold mounting apertures 293, 295 (FIG. 5B), in accordance with embodiments of the present disclosure. FIG. 5B depicts the bottom isometric view of the bridge portion 291 depicted in FIG. 5A, further depicting a conduit port 297 defined in a bottom connecting surface of the bridge portion 291, in accordance with embodiments of the present disclosure.

As depicted in FIGS. 5A and 5B, the bridge portion 291 can include additional manifold mounting apertures 293, 295 through which a manifold can be connected. For example, an ICS manifold, K1S manifold, or other type of manifold can be fluidly coupled with the conduit port 297 defined in the bottom connecting surface 299 of the bridge portion 291. As further depicted in FIG. 5B, while alignment pins are depicted as protruding from the bottom connecting surface 299 of the bridge portion 291, some embodiments can include no alignment pins in view of the corresponding flared connection protrusion and flared connection depression, as discussed herein.

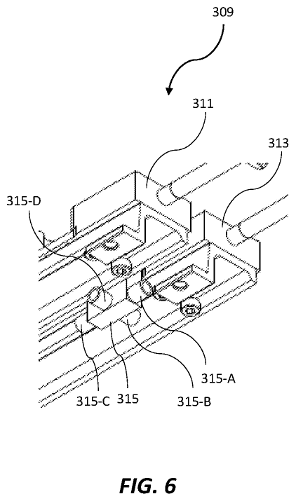

FIG. 6 depicts a modular flow substrate that includes a pair of flow substrates 311, 313 coupled with one another via a bridge portion (hidden from view) and a multiport manifold 315, in accordance with embodiments of the present disclosure. As depicted, the first flow substrate 311 and the second flow substrate 313 can be connected with one another via a bridge portion, which is hidden from view. The flow substrates 311, 313 can each include the same or similar features to those discussed in relation to flow substrate 231, depicted in FIG. 3. For example, as depicted, flow substrate 311 can include a flared connection depression 317, into which a flared connection protrusion can be inserted.

In some embodiments, the bridge portion can include a conduit port, to which the manifold 315 can be fluidly coupled. For example, with further reference to FIG. 5B, the manifold 315 can be fluidly coupled with the conduit port 297. In some embodiments, as depicted, the manifold can include a plurality of manifold conduit ports 315-A, 315-B, 315-C, 315-D, which can direct fluid and/or gas to a plurality of other fluid handling components.

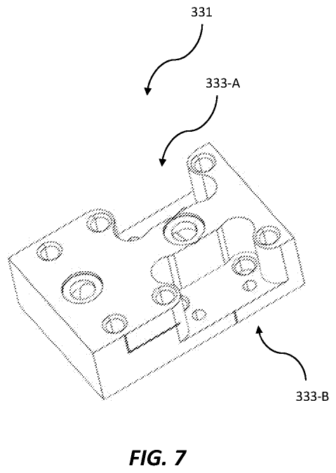

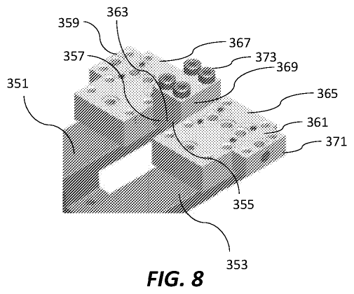

FIG. 7 depicts a flow substrate 331 with a pair of flared connection depressions 333-A, 333-B, in accordance with embodiments of the present disclosure. In some embodiments, the flow substrate may not include a manifold conduit port, as discussed herein, but can be used to couple one or more manifolds, as further depicted and discussed in relation to FIG. 8.

FIG. 8 depicts a pair of flow substrates (e.g., manifolds) 351, 353, fluidly coupled with one another, in accordance with embodiments of the present disclosure. In some embodiments, as discussed in relation to FIGS. 2A and 2B, the bridge portion can be a two sided bridge portion that includes opposing flared connection protrusions 209-A, 209-B. In some embodiments, as depicted in FIG. 8, the bridge portions 355, 357, 359, 361 can include one flared connection protrusion, as further discussed herein. With particular respect to bridge portions 355, 357, opposing ends of the bridges can be butted against one another to form a fluid tight seam 363.

As further depicted in FIG. 8, flow substrates 365, 367 can be coupled to the flow substrates 351, 353 and further connected to one another via the bridge portions 355, 357, and associated connection block 369. As depicted, the opposing bridge portions 355, 357 can include planar sealing surfaces, which can be the same or similar to planar sealing surface 371, associated with bridge portion 361. In some embodiments, the planar sealing surfaces can include one or more conduit ports, which can be fluidly coupled with opposing fluid conduit ports defined on adjacent planar sealing surfaces.

In some embodiments fasteners (e.g., bolts) 373 can extend through the connection block 369 and each respective bridge portion 355, 357. In some embodiments, the fasteners 373 can further extend into a manifold located below the flow substrates 365, 367, as depicted in FIG. 6, thereby fastening the connecting block, bridge portions 355, 357, flow substrates 365, 367, and manifold together.

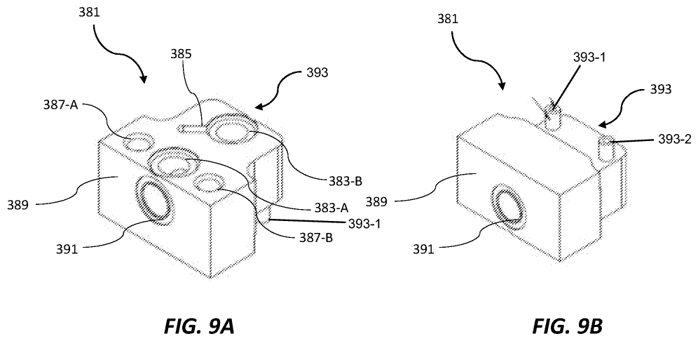

FIGS. 9A and 9B further depict isometric top and bottom views of the bridge portion 381 depicted in FIG. 8, in accordance with embodiments of the present disclosure. As depicted, the bridge portion 381 can include first and second conduit ports 383-A, 383-B, and a leak port 385. In some embodiments, the bridge portion 381 can include first and second connection apertures 387-A, 387-B. As further depicted, the bridge portion 381 can include a planar sealing surface 389 in which a fluid conduit port 391 is defined.

FIGS. 9A and 9B further depict a connection protrusion 393. For ease of illustration, the connection protrusion 393 depicted in FIGS. 9A and 9B is not depicted as including any flared portions as discussed herein. However, embodiments of the present disclosure can further include connection protrusions with flared portions, thereby defining a flared connection protrusion, as further discussed herein. Thus, in some embodiments, the bridge portion 381 depicted in FIGS. 9A and 9B can include a flared connection protrusion, versus what is depicted. As depicted in FIGS. 9A and 9B, the connection protrusions can have alignment pins 393-1, 393-2. The alignment pins 393-1, 393-2 can include the same or similar features as those discussed in relation to FIGS. 2A and 2B. For example, the alignment pins 393-1, 393-2 can be inserted into corresponding indexing lumens defined on a flow substrate.

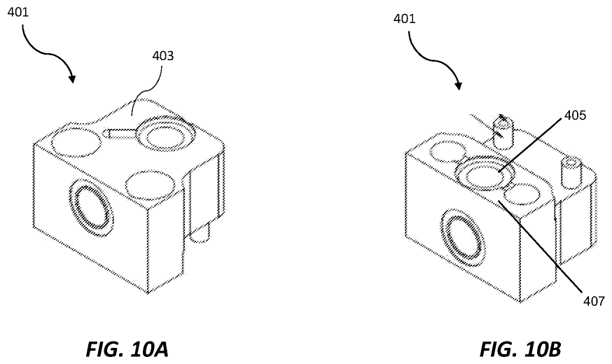

FIGS. 10A and 10B further depict isometric top and bottom views of a bridge portion 401, in accordance with embodiments of the present disclosure. The bridge portion 401 can include the same or similar embodiments as those discussed in relation to FIGS. 9A and 9B, with the exception that the bridge portion 401 can include a single conduit port defined in component attachment surface 403. As further depicted in FIG. 10B, the bridge portion 401 can include a conduit port 405 defined in the bottom connecting surface, which can for example be coupled to a flow substrate.

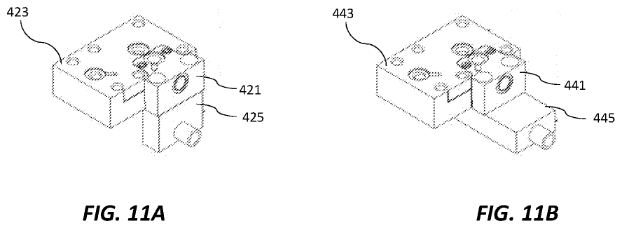

FIG. 11A depicts a top isometric view of a bridge 421 coupled with a flow substrate 423, along with a K1S manifold 425, in accordance with embodiments of the present disclosure. For ease of illustration, the connection protrusion associated with the bridge 421 depicted in FIG. 11A is not depicted as including any flared portions as discussed herein. However, embodiments of the present disclosure can further include connection protrusions with flared portions, thereby defining a flared connection protrusion, as further discussed herein. Thus, in some embodiments, the bridge portion 421 depicted in FIG. 11A can include a flared connection protrusion, versus what is depicted.

FIG. 11B depicts a top isometric view of a bridge 441 coupled with a flow substrate 443, along with an ICS manifold 445, in accordance with embodiments of the present disclosure. For ease of illustration, the connection protrusion associated with the bridge 441 depicted in FIG. 11B is not depicted as including any flared portions as discussed herein. However, embodiments of the present disclosure can further include connection protrusions with flared portions, thereby defining a flared connection protrusion, as further discussed herein. Thus, in some embodiments, the bridge portion 441 depicted in FIG. 11B can include a flared connection protrusion, versus what is depicted.

It will be appreciated that details of the foregoing embodiments, given for purposes of illustration, are not to be construed as limiting the scope of the present disclosure. Although several embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure, which is further defined in the converted utility application and appended claims. Further, it is recognized that many embodiments may be conceived that do not achieve all the advantages of some embodiments, particularly preferred embodiments, yet the absence of a particular advantage shall not be construed to necessarily mean that such an embodiment is outside the scope of the present disclosure.

What is claimed is:

1. A delivery system comprising:
a bridge portion, wherein the bridge portion includes a flared connection protrusion.

2. The delivery system of claim 1, wherein the flared connection protrusion includes a first lobe portion and a second lobe portion.

3. The delivery system of claim 2, wherein the first lobe portion and the second lobe portion define first and second mounting apertures extending therethrough.

4. The delivery system of claim 1, wherein the bridge portion further comprises:
a fluid delivery substrate attachment surface; and
an alignment pin extending from the fluid delivery substrate attachment surface.

5. The delivery system of claim 1, further comprising a flow substrate, wherein the flow substrate includes a flared connection depression.

6. The delivery system of claim 5, wherein the flared connection protrusion is configured to be inserted into the flared connection depression, thereby limiting movement between the flow substrate and the bridge portion to movement in a single direction.

7. The delivery system of claim 6, wherein the bridge portion includes an alignment pin extending from a fluid delivery substrate attachment surface.

8. The delivery system of claim 7, wherein the flow substrate includes an indexing lumen that corresponds to the alignment pin.

9. The delivery system of claim 1, wherein:
the flared connection protrusion includes a first lobe portion and a second lobe portion; and
the first lobe portion and the second lobe portion are semicircular in shape.

10. A delivery system comprising:
a flow substrate, wherein the flow substrate includes a flared connection depression.

11. The delivery system of claim 10, wherein the flared connection depression is a semicircular lumen.

12. The delivery system of claim 11, wherein the flow substrate includes a connection surface at a base of the flared connection depression.

13. The delivery system of claim 12, wherein a mounting aperture is defined in the connection surface at a base of the flared connection depression.

14. The delivery system of claim 13, further defining a plurality of indexing lumens defined in the connection surface.

15. A delivery system comprising:
a bridge portion, wherein the bridge portion includes a flared connection protrusion; and
a flow substrate, wherein the flow substrate includes a flared connection depression, wherein the flared connection protrusion is configured to be inserted into the flared connection depression.

16. The delivery system of claim 15, wherein the bridge portion includes a conduit port.

17. The delivery system of claim 15, wherein the flared connection protrusion and the flared connection depression have corresponding shapes.
